(19) United States
(12) Patent Application Publication
(10) Pub. No.: US 2008/0053326 A1
(43) Pub. Date: Mar. 6, 2008

(54) Inkjet composite stereographic printing plate and method for producing such printing plate

(75) Inventors: Edward T. Murphy, Douglasville, GA (US); Thomas O. Gavin, Fairfield, NJ (US)

Correspondence Address: EMCH, SCHAFFER, SCHAUB & PORCELLO CO, P O BOX 916, ONE SEAGATE SUITE 1980, TOLEDO, OH, 43697, US

(73) Assignee: Anderson Vreeland

(21) Appl. No.: 11/888,105

(22) Filed: Jul. 31, 2007

Related U.S. Application Data
(60) Provisional application No. 60/840,835, filed on Aug. 29, 2006.

(51) Int. Cl. B41N 1/12; G03F 7/26

(52) U.S. Cl. 101/395; 430/306

(57) ABSTRACT

A method of making a relief image printing plate by means of application of successive layers of polymer on a composite structure using inkjets. Relief depth (Need explanation in description of invention) is able to be minimized by building required press undercut thickness by applying the inkjetted polymer on the surface of a pre-manufactured composite structure of at least two layers; one an elastic polymeric material and one providing dimensional stability. An article—a relief image printing plate made by means of application of successive layers of polymer on a composite structure using inkjets in which a compressible layer is between the print layer and a dimensionally stable layer.

### CROSS REFERENCE TO RELATED APPLICATION

This application claims the benefit of U.S. provisional patent application Ser. No. 60/840,835 filed Aug. 29, 2006.

### BACKGROUND OF THE INVENTION

An example of stereographic (relief printing plates is that of Flexographic printing plates. Flexographic plates are commonly used in the printing of packaging materials like corrugated boxes, folding cartons, plastic films and labels. They have a printing surface of elastomeric, polymeric material capable of conforming to the ink supply roller (called an anilox roll) and also to the contour of the product being printed. The surface is relieved (cut away) in places where ink is not desired. The polymer of the printing plate is designed chemically for compatibility with the inks used and mechanically for the hardness and elasticity required to accomplish ink transfer without damage to the products being printed and in consideration of the printing press speed and configuration. The relief images of plates are almost universally produced by subtractive development of selectively cross-linked polymers.

Selective cross-linking is achieved when ultraviolet light (UV) is used to crosslink the transparent polymer from the back of the plate through a polyester backing sheet to establish a solid base called the floor and then ultraviolet light is selectively exposed to the surface of the plate in the pattern of the desired image to crosslink the printing surface and cure through to the already established floor. The selective exposure is done through a photographic negative or a carbon black coating from which the opposite selective areas have been ablated thereby allowing UV light to pass through.

Subtractive development then takes place using a process like chemical or thermal etching, or laser engraving to remove the unwanted volume of plate surface material thus leaving the desired image. The process of removing unwanted material commonly 1) uses volatile organic compounds that must be handled carefully, ventilated properly and produces waste that must be post-treated or 2) uses water that after development contains dissolved polymer and often surfactants and whose discharge must be treated, monitored or both 3) produces gaseous exhaust vapors that require filtering.

A typical Flexographic printing plate is constructed of a layer of polyester film (usually 0.005 inches thick), a thin adhesive bonding layer and one or more layers of photopolymeric material. The total thickness of these plates commonly range from 0.030 inches to 0.250 inches. After plates are processed and have on them the images that are desired to be printed, the plates are mounted on printing cylinders or sleeves that are then placed on cylinders. Attachment of the printing plate to the printing cylinder or sleeve is by means of double sided adhesive tape (mounting tape) that commonly is between 0.020 and 0.060 inches thick and most often mounting tapes have compressible properties. Printers choose the mounting tape based on a number of factors including: printing press design and condition, operating speed, substrate being printed and image characteristics. For instance, a fragile substrate like film, with a fine image resolution of 150 lines per inch (lpi) on an old printing press that inherently vibrates may require a soft compressible, thick mounting tape. But a simple image of block letters running on a different press may simply be mounted with thin tape with no compressibility.

The concept of using an inkjet device to build a three dimensional object (called 3-D modeling) is well known. Masters (U.S. Pat. No. 5,134,569) describes a system and method for constructing a three-dimensional object using UV curable polymers dispensed from a nozzle. Peer (U.S. Pat. No. 5,313,232) describes a method of constructing a three-dimensional object using an inkjet with ink that is thermally jetted as a liquid and changes phase to a solid upon cooling. Schmidt, et al. (U.S. Pat. No. 6,841,589) discloses an ink jettable polymer composition for 3D modeling that is both UV curable and undergoes phase change upon application. Application of 3D modeling to the production of a relief printing plate by jetting polymer only where the printing surface is desired (additive process) has been disclosed by Adler, et al. (U.S. Pat. No. 5,511,477) and is considered by Gelbart (U.S. Pat. No. 6,520,084). However, there are serious practical problems in doing this since building a printing plate that is typically 0.067 inches to 0.250 inches thick is 1) time consuming, 2) difficult to maintain thickness control to desired tolerances and 3) after building up the full thickness of the plate, the surface smoothness is often unacceptable. Gelbart addresses this later problem when he describes inverting the plate and applying the print surface polymer to a smooth platen and utilizing a sacrificial polymer for the relief area, but once again a subtractive development process must be utilized to remove the unwanted sacrificial polymer.

### SUMMARY OF THE INVENTION

This invention relates to a method of making a printing plate by using one or more inkjets and/or inkjet heads to deposit elastic polymers on a substrate to form a relief printing image in a thickness range of between 0.005 to 0.035 inches. A relief image is a three-dimensional image similar to that of a common ink stamp in which the relief depth is the distance from the printing surface to base of the stamp. The substrate is a composite structure of material that consists of preferably, 1.) one or more elastomeric layers upon which a relief image is applied using one or more polymers, and optionally, 2.) a compressible foam layer and, 3.) a dimensionally stabile layer such as polyester film, and optionally, 3.) compressible foam layer and optionally, 4.) a mounting adhesive. This invention also relates to an article, specifically a printing plate, made with the above process where a compressible foam layer is positioned anywhere between the dimensional stable layer and the printing image formed by the inkjets and, optionally, a second compressible layer is positioned below the dimensionally stable layer.

It should also be noted that placing the compressible foam layer 6 between the printing image 4 and the dimensionally stable layer 8 is preferable as noted by Fischer, et al in U.S. Pat. No. 4,582,777 (Fischer) and Rach in U.S. Pat. No. 5,962,111 (Rach). While both Fischer and Rach refer to liquid photopolymer plates, its practical application with sheet photopolymer has repeatedly failed at the commercial level. This is because during storage, before a customer forms an image, migration of chemical components occurs in the photopolymer/foam composite plate. The rate of migration of chemical components is affected by temperature and increases as the temperature at which composite plate is stored. The migration occurs in two directions: 1) from the photopolymer to the foam layer and 2) from the foam layer to the photopolymer. First, chemical components, such as photoinitiators, that are monomeric in size or polymers, such as plasticizers, with very short chain lengths migrate from the photopolymer to the foam. The result is that the designed, predictable, imaging properties of the photopolymer are not achieved and the compressible layer physical properties are also changed. And secondly, after imaging a composite sheet photopolymer-foam plate, storage of the plate leads to migration of plasticizers found in the components (usually, the foam) which cause adhesion failure between the foam and the photopolymer as noted Umeda, et al in U.S. Pat. No. 4,582,777 (Umeda).

Other objects and advantages of the present invention will become apparent to those skilled in the art upon a review of the following detailed description of the preferred embodiments and the accompanying drawings.

### BRIEF DESCRIPTION OF THE DRAWINGS

FIG. 1 is a perspective view of a printing plate with raised three-dimensional (relief) images typical of that to be made utilizing the invention.

FIG. 2 is perspective view of the inkjet equipment and printing plate.

FIG. 3 is a partial perspective view of the inkjet taken from FIG. 2.

FIG. 4 is an exploded partial perspective view of a printing plate formed utilizing the present invention.

FIG. 5 is an exploded partial perspective view of an alternative printing plate of the present invention.

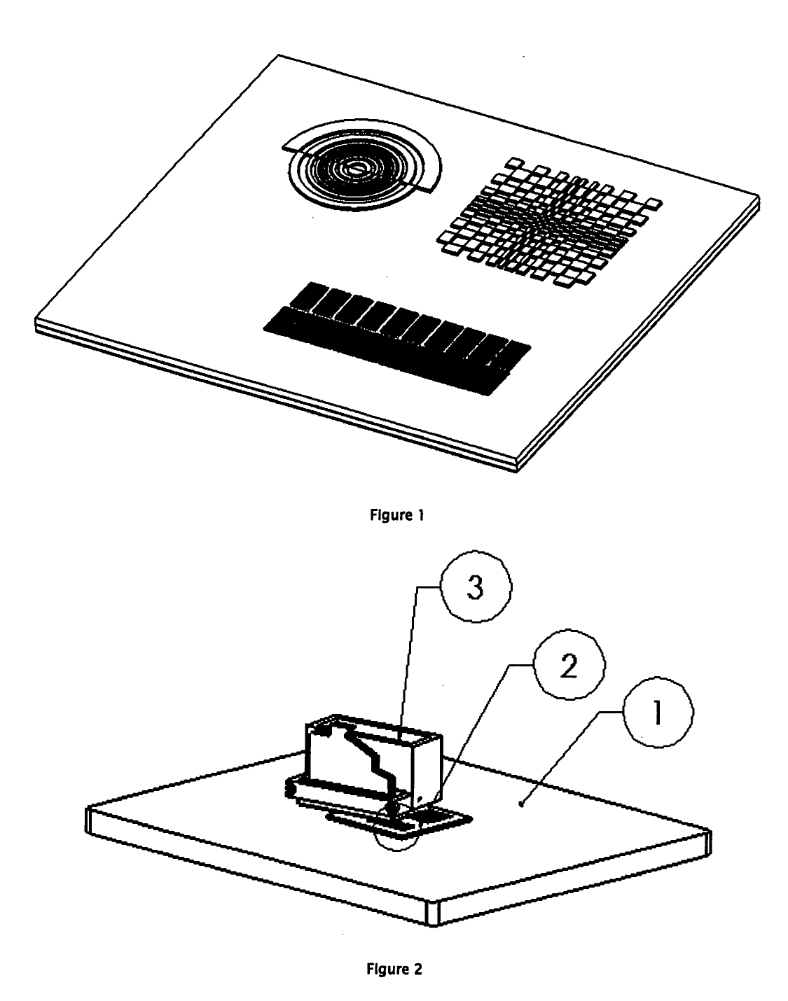

### DETAILED DESCRIPTION OF THE PREFERRED EMBODIMENT(S)

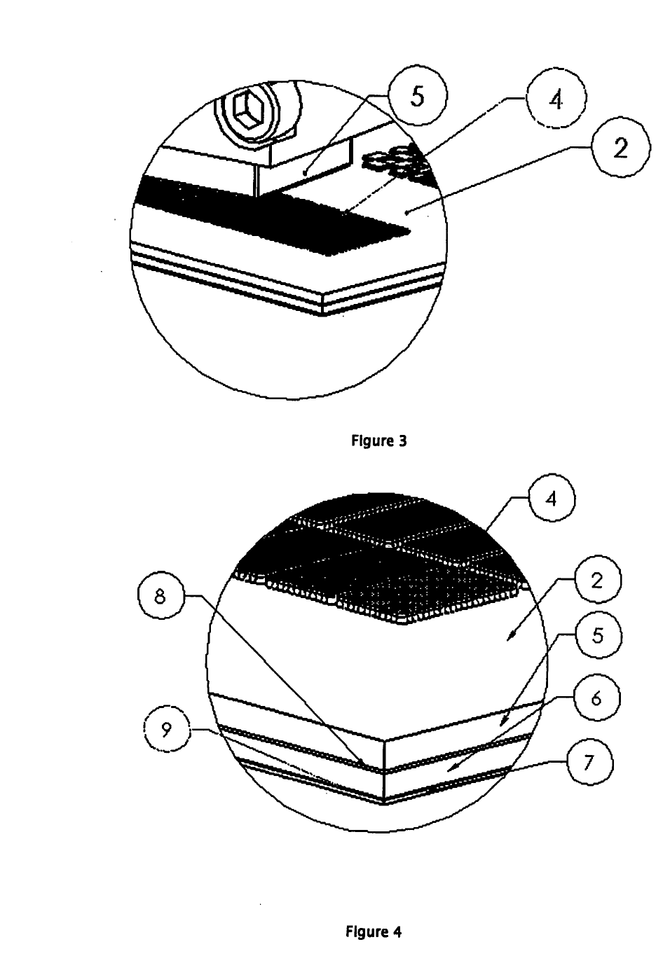

The apparatus used to construct a composite relief printing plate by means of inkjet as described in the invention can utilize numerous devices used for rapid prototyping such as the Eden 330 series manufactured by Objet Geometries Ltd of Rehovot, Israel or the Vantage system manufactured by Stratasys, Inc. of Eden Prairie, Minn. The basic elements of the apparatus for the purpose of describing this invention are shown in FIGS. 2 and 3 and consists of an inkjet head assembly 3 and a construction platen 1 on which the printing plate preparatory elements or backing 2 are placed (also shown in FIG. 3) and on which polymer printing image is deposited by the inkjet head assembly.

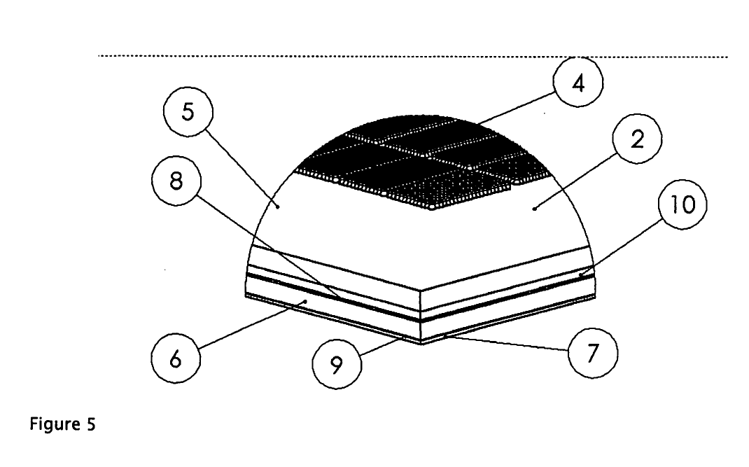

The printing plate is formed by placing a pre-manufactured, composite, base or backing 2 on the construction platen 1 under an inkjet bead assembly 3 such as an Eden 330 series rapid prototyping machine. The backing is constructed from elements best suited for the particular printing conditions. Based on printing press configuration, speed, ink chemistry, and substrate being printed the prepared backing 2 preferably will consist, as shown in FIGS. 4 and 5, of: a solid polymer 5 (Examples of this polymer and thickness of this layer-no support for language in the claims on the polymer?) of high resilience having a durometer range between 25 and 80 Shore A. An example of such a polymer would be a cross linked Styrene-Isoprene-Styrene (SIS) block co-polymer such as manufactured by Shell Chemical under the brand name of Kraton 1107; a first compressible layer 10 such as a polyethylene closed cell foam like #52508 manufactured by Tesa Tape, Inc. of Charlotte, N.C. or a polyurethane closed cell foam like #4032 manufactured by 3M Company of Minneapolis, Minn.; a dimensionally stable layer 8 of a thickness of 0.005 inches such as polyester film such as ESTAR film manufactured by Kodak; a second foam or compressible layer 6 with foam properties like SA 3300 manufactured by Rogers Corporation of Woodstock, Conn. or a polyurethane closed cell foam like #4032 manufactured by 3M Company of Minneapolis, Minn.; some foam layers may not have adhesive properties and in that case an appropriate adhesive 9 is required to allow the finished article to be mounted on a printing cylinder; and a release liner 7 that is only removed from the finished article at the time of mounting to the printing cylinder. In the preferred embodiment with a first and second compressible layer, the hardness (force required to deform a given distance) of the first layer closest to the print surface should be softer than the second layer. The total deformability (void volume) of the second compressible layer farthest from the print surface should be the greater than the first compressible layer closest to the print surface. This results in the fine printing and conformability to the printed substrate controlled primarily with the thin, softer layer and the thicker, harder layer providing protection to the plate from larger displacements such as press gear bounce or wrinkles in the printed substrate.

Once the composite backing 2 is chosen and ready for application of the printing image, the backing is placed on the platen 1 (FIG. 2). The inkjet assembly 3 (FIG. 2) scans back and forth (x direction) advancing across the platen (y direction) depositing, in an image wise fashion, polymer from the inkjet head 3 (FIG.3) until the desired printing image has been deposited on the surface of the plate.

The platen 1 (FIG.2) is then lowered (z direction) a preset increment and the scanning process is repeated. The Inkjet assembly 3 only deposits the image that is to be printed by the printing plate. Accordingly, it is not necessary to remove polymer from the surface of the printing plate to form the desired print image.

The polymer that is applied by the inkjet assembly is elastomeric in nature as is the polymer that is used to form the polymer layer 5 of the backing 2. Physical properties such as modulus, elongation and durometer may be varied to optimize printing quality in consideration of the printing conditions. For instance, when printing an absorbent material such as paper towels a harder, less deformable printing layer may improve image sharpness. If more than one inkjet is utilized it is possible to vary the durometer value in different layers of the polymer. In practice it has been found desirable to vary the durometer value of the polymer by 10 or more Shore A points when different grades of polymer are applied to the backing 2. The printing properties are critically influenced by the surface of the printing plate. Parameters such as roughness, abrasiveness, surface tension, surface tack and solvent resistance have a great influence on ink transfer and the impression characteristics. It is known to construct printing plates from a plurality of layers, especially two layers. The two-layer construction of a printing plate, comprising a photopolymerizable layer and a relatively thin, photopolymerizable top layer located thereon, has the advantage that the imaging and mechanical properties of the surface of the printing plate can be modified without affecting the typical properties of the printing plate such as, for example, hardness or elasticity. Surface properties and layer properties can therefore be modified independently of one another in order to achieve the optimum printing result.

The polymer that is applied by the inkjet to form the printing image can be a photo-curing polymer. Such a photo-curing polymer is liquid at room temperatures or heated to a liquid state to allow the polymer to be applied by the inkjet. Exposing the polymer to radiation after application to the backing results in an at least partial cross-linking of the polymer that solidifies the polymer. In practice it has been found that radiation having a wavelength between 250-400 nm works particularly well to cross-link the polymer. Solidification after inkjetting occurs with cross linking in the case of polymers that are liquid at room temperature or upon cooling with those polymers that are solid at room temperature.

Photopolymer plates that are solid at room temperature prior to UV exposure are commonly manufactured with elastomeric block copolymers. The elastomeric block photopolymer is usually a polystyrene-isoprene-polystyrene block copolymer of a polystyrene-polybutadiene-polystyrene block copolymer. Photopolymer plates that are liquid prior to UV exposure are commonly manufactured with urethanes, usually composed of polyester, polyether or blends of both. For both classes (solid at room temp and liquid at room temp) there are other polymers but these encompass the vast majority of what is used today.

The above detailed description of the present invention is given for explanatory purposes. It will be apparent to those skilled in the art that numerous changes and modifications, other than those cited, can be made without departing from the scope of the invention. Accordingly, the whole of the foregoing description is to be construed in an illustrative and not a limitative sense, the scope of the invention being defined solely by the appended claims.

I claim:

1. A method of making a polymeric surfaced relief printing plate comprising:
positioning a pre-manufactured composite structure comprised of at least one elastomeric layer and a dimensionally stabilizing on an inkjet device;
applying successive applications of polymer to the pre-manufactured composite by means of an inkjet device to form the relief printing image;

2. The method of claim 1 in which the pre-manufactured composite structure has a compressible layer between the relief printing image and the stabilizing layer.

3. The method of claim 2 where the pre-manufactured composite structure has a compressible layer positioned on the side of the dimensionally stabilizing layer that is opposite the relief printing image.

4. The method of claim 1 in which multiple inkjet heads of are utilized to form the relief printing image.

5. The method of claim 4 in which the multiple inkjet heads apply polymers of durometers differing by 10 or more Shore A points.

6. The method of claim 1 in which the polymer is photo curing wherein the polymer is liquid at ambient temperature and upon discharge from the inkjet device is exposed to radiation of a wavelength to effect at least partial cross linking of the polymer resulting in solidification of the polymer.

7. The method of claim 6 in which the wavelength required to effect cross linking is between 250 nm and 400 nm.

8. The method of claim 1 in which the polymer is a solid at room temperatures is heated to a liquid state appropriate for inkjet application and cools upon application to pre-manufactured composite wherein the polymer re-solidifies to form the required printing image.

9. The method of claim 8 in which the polymer is photo curing.

10. The method of claim 9 in which the wavelength required to effect cross linking is between 250 nm and 400 nm.

11. The method of claim 1 in which the pre-manufactured composite structure contains a layer that is a contact adhesive for attachment of the printing plate to a printing press.

12. A polymeric surfaced relief printing plate comprising:
a pre-manufactured composite structure having at least one elastomeric layer and a dimensionally stabilizing; and
a relief printing image positioned on the pre-manufactured composite structure, the relief printing image formed by depositing successive layers of a polymer by an inkjet device, the polymer only being applied to the pre-manufactured composite structure in the area of relief printing image.

13. The polymeric surfaced relief printing plate of claim 12 wherein a compressible layer is positioned between the printing surface and the dimensionally stabile layer.

14. The polymeric surfaced relief printing plate of claim 13 wherein an additional compressible layer positioned on the opposite side of the dimensionally stabile layer.
